(19) United States
(12) Patent Application Publication
(10) Pub. No.: US 2017/0040138 A1
(43) Pub. Date: Feb. 9, 2017

(54) X-RAY WINDOW

(71) Applicant: UHV Technologies, Inc., Fort Worth, TX (US)

(72) Inventors: Nalin Kumar, Fort Worth, TX (US); Geunhee Lee, Plano, TX (US)

(21) Appl. No.: 15/227,594

(22) Filed: Aug. 3, 2016

Related U.S. Application Data
(60) Provisional application No. 62/200,473, filed on Aug. 3, 2015.

(51) Int. Cl. H01J 5/18; C23C 16/27; C23C 16/511

(52) U.S. Cl. CPC H01J 5/18; C23C 16/511; C23C 16/27

(57) ABSTRACT

An x-ray window, which may be utilized within an x-ray source or an x-ray detector is disclosed, and a method for manufacturing the same. The x-ray window may be permeable to soft x-rays. The x-ray window may have at least one surface in contact with a pressure essentially equal that of a vacuum. The x-ray window may be multilayered with a thickness of less than or equal to one micron.

This patent application claims priority to U.S. provisional patent application Ser. No. 62/200,473, which is hereby incorporated by reference herein.

### GOVERNMENT LICENSE RIGHTS

This invention was made with U.S. government support under Grant No. DE-SC0001187 awarded by the U.S. Department of Energy. The U.S. government may have certain rights in this invention.

### TECHNICAL FIELD

The present invention relates in general to x-ray windows, such as for use with x-ray sources and detectors.

### BACKGROUND INFORMATION

There is a need to develop very thin, low cost x-ray detector windows (<100 μg/cm²) with >50% transmission at 500 eV x-rays for gaseous detectors, in order to measure low energy ions (carbon 277 eV, nitrogen 392 eV, oxygen 525 eV, fluorine 677 eV, and sodium 1.04 keV), because the most popular 8-12 μm thick beryllium (Be) windows from Materion (previously known as Brush Wellman) are opaque in this region. Beryllium, being a lighter element than carbon, should be a better window material than diamond; however, beryllium requires a. thickness in the 8-12 μm range to assure a vacuum-tight and mechanically strong window. Recently, Moxtek has developed proprietary plastic (polypropiene) windows (trade name AP1-AP3); however, these are temperature limited and cannot be hermetically sealed (e.g., see U.S. Pat. No. 8,964,943). Diamond has long been considered an ideal material for low energy x-ray windows due to its strength, corrosion resistance, high transparency, high thermal conductivity, and radiation tolerance. In fact, the first CVD diamond windows (0.4 micron thick) were reported by Crystallume, Calif. in 1989, and showed a transmission of 22.5% for Oxygen Kα [Peters et al. 1989]. In 1992, NIST reported a transmission of 27% for a 0.3 CVD diamond film. In 2003, Fudan University in China reported 59% transmission at 284 eV for 0.4-0.5 micron thick CVD diamond windows [Ying 2003]. Even though numerous groups around the world have published papers describing results on CVD diamond windows over the last 20 years, there is no supplier of CVD diamond windows in the world, presumably due to the high manufacturing cost of CVD diamond films. Recently, PN Detector from Germany showed brochures of x-ray windows material unknown) with 46% transmission for 0-525 eV x-ray's at the recent Denver X-ray Conference; but, according to them, these are not commercially available for foreseeable future.

### BRIEF DESCRIPTION OF THE DRAWINGS

FIGS. 1A and 1B illustrate schematic diagrams of multilayer structures for x-ray windows configured in accordance with embodiments of the present invention.

FIGS. 2A, 29, 2C, 2D, and 2E illustrate fabrication of an x-ray window in accordance with embodiments of the present invention.

FIG. 3 shows a digital image of an exemplary x-ray window fabricated in accordance with embodiments of the present invention.

FIGS. 4A, 4B, 4C, 4D, 4E, 4F, and 4G show graphs of x-ray transmissions for various combinations of x-ray window materials.

FIG. 5 illustrates an x-ray tube and detector configured in accordance with embodiments of the present invention.

### DETAILED DESCRIPTION

While these exemplary embodiments are described in sufficient detail to enable those skilled in the art to practice the invention, it should be understood that other embodiments may be realized and that various changes to the invention may be made without departing from the spirit and scope of the present invention. Thus, the following more detailed description is not intended to limit the scope of the invention, as claimed, but is presented for purposes of illustration only to describe the features and characteristics of the present invention, to set forth the best mode of operation of the invention, and to sufficiently enable one skilled in the art to practice the invention. Accordingly, the scope of the present invention is to be defined solely by the appended claims.

As used in this description and in the appended claims, the words “film” and “layer” mean a continuous layer, and do not mean a divided structural support such as a plurality of ribs or support members. As used herein, the terms “tight” and “tightness” refer to a characteristic of a physical configuration being able to substantially or completely' restrict passage of a specified parameter, such as a gas or optical light.

Embodiments of the present invention may be configured as a window member to be used in an optical device, such as a system employing ultraviolet light, visible radiation, infrared radiation, and/or x-ray's.

Embodiments of the present invention provide an x-ray window and its fabrication method, and more specifically, to such a window made out of low-Z materials (e.g., carbon (C; diamond, diamond-like carbon, graphite, etc.), boron (B), and/or nitrogen (N)), with a high strength base layer (e.g., silicon nitride (Si₃N₄)).

As is well-known, x-rays can be generated by the bombardment or irradiation of a metal target by a beam of electrons. The target and electron beam may be contained within an evacuated (e.g., vacuum) chamber for the proper generation and acceleration of the electron beam. X-rays include electromagnetic radiation of extremely short wavelength. “Hard” x-rays are generally defined as x-rays with wavelengths shorter than a few angstroms, while “soft” x-rays have wavelengths of tens of angstroms or more. For example, carbon K-alpha x-rays have wavelengths of approximately 44 angstroms, and, thus, are son x-rays.

Hard x-rays can be used to analyze the composition and structure of matter having relatively high atomic mass. The hard x-rays are formed within the evacuated chamber and are then beamed out of the chamber through a “vacuum window” towards the sample to be tested. The vacuum window needs to be capable of withstanding continuous x-ray bombardment and a pressure differential of approximately one atmosphere. Light elements such as hydrogen or oxygen cannot be detected with hard x-rays because they tend to ionize and otherwise react with the x-rays. Therefore, lower energy, soft x-rays would have to be used to detect light elements. Unfortunately, soft x-rays are not sufficiently energetic to adequately penetrate most prior art vacuum windows. For example, a prior art vacuum window that can pass a significant percentage of incident hard x-rays may only pass a fraction of a percent of incident soft x-rays.

First, as a property of the material of good x-ray windows, high transparency for x-rays is required. Secondly, high strength is required. An x-ray window should be very thin in order to decrease the absorption of x-rays. Conventional x-ray windows have employed beryllium (Be) as the material of the film. Beryllium is strong enough even in the form of a thin film. The absorption of x-rays is comparatively small, because the atomic weight of beryllium is small. However, even beryllium windows must be thicker than several tens of microns to ensure the mechanical strength as a window. Such thick beryllium windows exhibit strong absorption of the x-rays scattered from light elements. Thus, the kinds of detectable elements are restricted for an x-ray detector with a beryllium window.

Standard x-ray windows typically include a sheet of material, which is placed over an opening, aperture, or entrance through which the x-ray beams pass. As a general rule, the thickness of the sheet of material corresponds directly to the ability of the material to pass radiation. Accordingly, it is desirable to provide a sheet of material that is as thin as possible, yet capable of withstanding pressure resulting from gravity, normal wear and tear, and differential pressures. It is therefore desirable to minimize attenuation of the x-rays (especially with low energy x-rays, ≦2 keV), thus it is desirable that the film is made of a material and thickness that will result in minimal attenuation of the x-rays. Thinner films attenuate x-rays less than thick films.

The film cannot be too thin, however, or the film may sag or break. A sagging film can result in cracking of corrosion resistant coatings. A broken film can allow air to enter the enclosure, often destroying the functionality of the device (e.g., x-ray source, x-ray detector). Thus, it is desirable to have a film that is made of a material that will have sufficient strength to avoid breaking or sagging, but also as thin as possible for minimizing attenuation of x-rays,

Since it is desirable to minimize the thickness in the sheet of material used to pass radiation, it is often necessary to support the thin sheet of material with a support structure. Known support structures include frames, screens, meshes, ribs, and grids. While useful for providing support to an often thin and fragile sheet of material, many support structures can interfere with the passage of radiation through the sheet of material due to the structure's geometry, thickness, and/or composition. The interference can be the result of the composition of the material itself and/or the geometry of the support structure.

In addition, many known support structures have drawbacks. For example, screens and meshes can be rough and coarse, and thus the overlaid thin film can stretch, weaken, and burst at locations where it contacts the screen or mesh. A drawback associated with ribs is that the ribs can twist when pressure is applied. This twisting can also cause the overlaid film to stretch, weaken, and burst.

Certain of the support structures can introduce stress concentrations into the window due to their structure (such as wire meshes), have different thermal conductivity than the window and introduce thermal stress, and can themselves interfere with the radiation directly or even irradiate and introduce noise or errors. In addition, difficulty can arise in the manufacture of these supports, thus making these support structures costly and expensive.

Therefore, it is desirable to develop an economical x-ray window that is thin as possible and as strong as possible while resisting the introduction of noise or interference with the x-ray radiation.

X-ray windows are often used with x-ray detectors. In order to avoid contamination of an x-ray spectra from a sample being measured, it is desirable that x-rays impinging on the x-ray detector are only emitted from the source to be measured. Unfortunately, x-ray windows can also fluoresce and thus emit x-rays that can cause contamination lines in the detected x-ray spectra. Contamination of the x-ray spectra caused by low atomic number (low-Z) elements is usually less problematic than contamination caused by higher atomic number elements. It is desirable, therefore, that the x-ray window and its structure be made of materials with as low of an atomic number as possible in order to minimize this noise.

Diamond (carbon) is a good material for low energy x-ray windows due to its strength (e.g., high Young's modulus), corrosion resistance, high transparency, high thermal conductivity, radiation tolerance, and low absorption coefficient for x-rays.

However, x-ray windows are generally used under within severe environments. For example, in the case of an energy dispersive x-ray microspectrometer, there is a considerable difference of pressure between the front and the back of the x-ray window. Often, as for example in connection with x-ray spectrometers, such x-ray windows need to be able to withstand pressure differentials of an atmosphere or greater. The pressure difference makes the x-ray window press inward. As a result, a high mechanical strength is required for the x-ray window. A diamond film thinner than a few micrometers cannot satisfy the requirement for strength. On the contrary, a thick diamond film that has sufficient mechanical strength would not be desirable because of the large absorption of x-rays. Silicon nitride is a high strength membrane forming material. Therefore, embodiments of the present invention combine these two materials diamond and silicon nitride) as a layered structure, which is thin less than 1 μm, more specifically less than 0.5 μm), and which is transparent to x-rays, especially for soft x-rays (e.g., ≦2 keV), and which can be utilized to form part of an x-ray apparatus.

Furthermore, embodiments of the present invention provide an x-ray window in such a multilayer and ultrathin form without having to resort to the utilization of a supporting structure positioned across the aperture of the x-ray window through which the x-rays pass, such as a lattice structure, cross members, intersecting ribs, grid structure, etc.

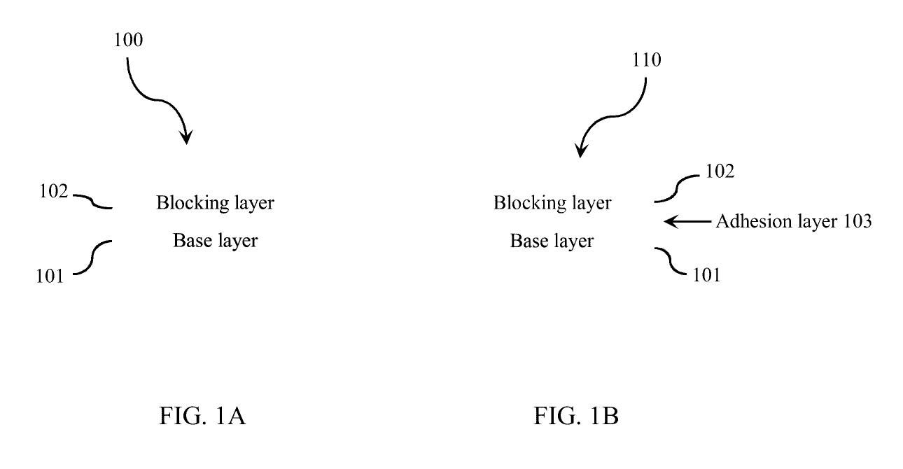

Therefore, referring to FIGS. 1A and 1B, a structure of an x-ray window configured in accordance with embodiments of the present invention is a multilayer structure with leak-vacuum tight, optical light transmission tight, high x-ray transmission, and corrosion resistance. The base layers 101 of such a multilayer structure with high mechanical strength and high x-ray transmission may be Si₃N₄, C, 9, Be, BN, CN, BeN, CNO, BNO, BO?, BeO₂, and/or LiF, which are all low-Z materials. Another layer may be an optical light blocking layer 102, which may have Al, B, and/or C elements. This layer 102 is to enhance optical light tightness. An Al layer normally allows tunable and efficient filtering of unwanted wavelengths (e.g., sunlight or UV radiation depending on the application), and also provides improved gas impermeability to the window. In embodiments of the present invention, the multilayered structure 100, 110 may be a combinational structure of a base layer 101 and an adjacent light blocking layer 102 with high mechanical strength and high x-ray transmission, (for example, diamond/C+B, diamond+graphite/C, diamond/C+Si₃N₄, etc.).

Referring to FIG. 1B, another layer can be an adhesion layer 103 (e.g., Al, Ti, and/or Cr) with very thin of angstrom (A) range, which may be utilized to enhance the adhesion between the base layer 101 and blocking layers 102.

Each layer in the x-ray windows 100, 110 can have various thicknesses, i.e., base layer: 20-200 nm, light blocking layer: 20-200 nm, adhesion layer: a few ∪, with a total thickness ≦1 μm. Furthermore, there is no limitation to the number of such layers.

Fabrication of such a multilayer structure may utilize a combination of pulsed laser deposition (“PLD”), chemical vapor deposition (“CVD”), and/or evaporation processes. Diamond (carbon) film may be deposited by PLD, microwave plasma CVD, or a hot filament CVD method. The vapor phase synthesis method may include supplying a material gas e.g., methane) and a carrier gas (e.g., hydrogen and/or argon) on a heated substrate, exciting the gases by some means to induce vapor phase reaction, and depositing the material borne by the reaction onto the substrate. Most of the base layer 101 may be deposited by a PIA) or CVD method. For example, the silicon nitride (Si₃N₄) layer may be deposited by low pressure CVD (“LPCVD”). Most of the metallic layer (adhesion layer 103 and/or light blocking layer 102) may be deposited by evaporation or a sputtering method. Therefore, the whole multilayered structure (e.g., 100, 110) may be built by various combinations of the foregoing deposition methods. Furthermore, embodiments of the present invention may utilize photolithography processes, which may include utilization of photoresist and mask layers for patterning various aspects of the structure. Within certain embodiments of the present invention, a layer or film may be effected by any of the previously disclosed methods such as, for example, hot CVD method, plasma CVD method, optical CVD method, ionized vacuum deposition method, ion beam method, and plasma jet method. Which of these methods is employed is not particularly

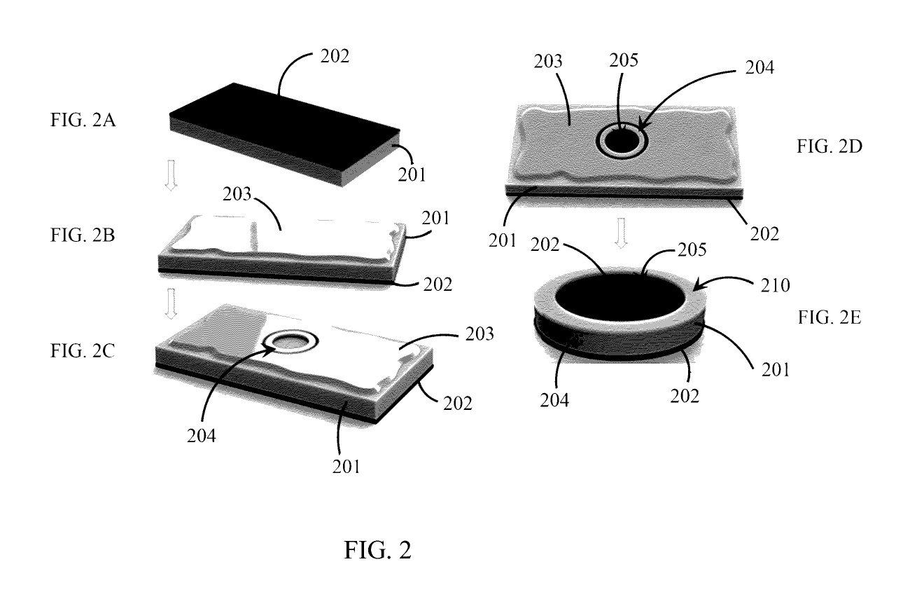

Referring to FIGS. 2A-2E, an x-ray window 210 configured in accordance with embodiments of the present invention may have a ring-type structure. A multilayer film may be sustained by a silicon (Si) ring substrate, although the peripheral part of the substrate may be left unetched, while the central part may be partially or fully etched. If desired, further unetched parts can constitute reinforcing crosspieces (not shown) made from the silicon, because they are originally parts of the silicon substrate. This structure may be fabricated by a plasma-therm and wet etching process. The silicon substrate may be etched through the pattern up to the window materials by wet or a plasma etching process. Once the etching step reaches the multilayer window materials, the ring-type window structure may be easily separated from the substrate.

FIGS. 2A-2E illustrate a process for manufacturing an x-ray window 210 in accordance with embodiments of the present invention. FIG. 2A illustrates a first step in the process whereby the various layers for the x-ray window are deposited onto a substrate. As previously disclosed with respect to FIGS. 1A-1B, and as noted elsewhere in this application, the x-ray window materials may include one or more layers of materials to produce a multilayer x-ray window film, which are transmissive to x-rays. Though FIGS. 1A-1B provide examples of such x-ray windows in which a light blocking layer has been included, embodiments of the present invention do not require such a light blocking layer 102. In embodiments of the present invention, the substrate may be a silicon (Si) wafer 201 on which one or more layers of window materials 202 are deposited thereon.

A silicon nitride (Si₃N₄) layer 202 may be deposited by low pressure chemical vapor deposition (“LPCVD”). The deposition may be performed on both sides of a Si wafer with a front side of the Si₃N₄ film 202 performing as the window for the x-ray beam, and a back side of the Si₃N₄ film 202 performing as a hard mask to enable the selective etching of the Si substrate 201 to define an aperture (see FIGS. 2C-2E) covered with a Si₃N₄ window (film) deposited on the opposite side of the wafer 201.

Within embodiments of the present invention, further window materials may be deposited onto the silicon wafer 201. For example, a silicon carbide (“SiC”) film may be deposited using a plasma enhanced chemical vapor deposition (“PECVD”) process. Within an exemplary embodiment of the present invention, such a SiC film may have about a 500 nm thickness. Furthermore, embodiments of the present invention may include a diamond layer deposited as one of the layers 202 on the silicon wafer 201. Within embodiments of the present invention, such a diamond layer may be an ultrananocrystalline diamond (“UNCD”) film. The UNCD film deposition may be performed using hot filament chemical vapor deposition (“HFCVD”), involving an array of parallel tungsten filaments heated to about 2200° C. to crack CH₄ molecules upon impact on the filaments, producing the C-based species that induce the growth of the UNCD film.

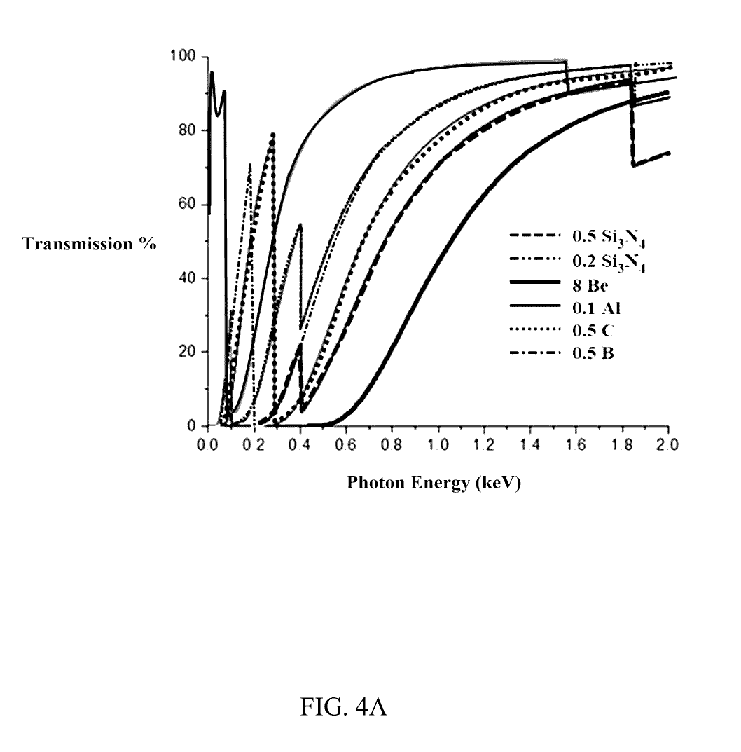

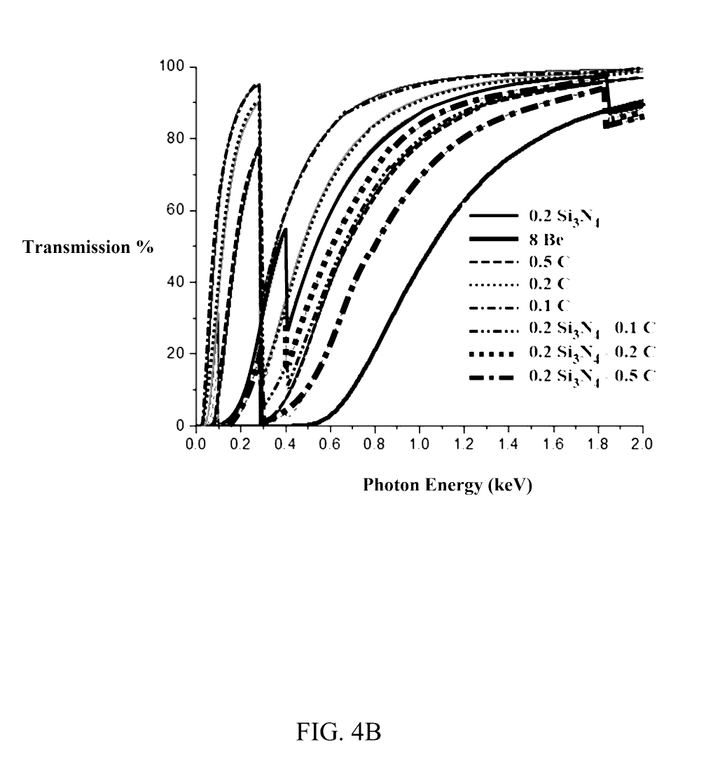

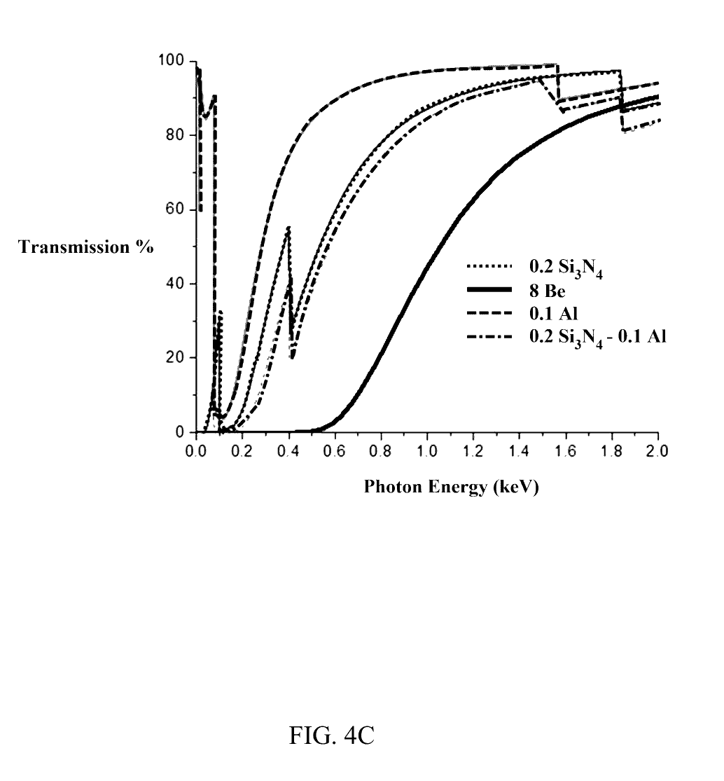

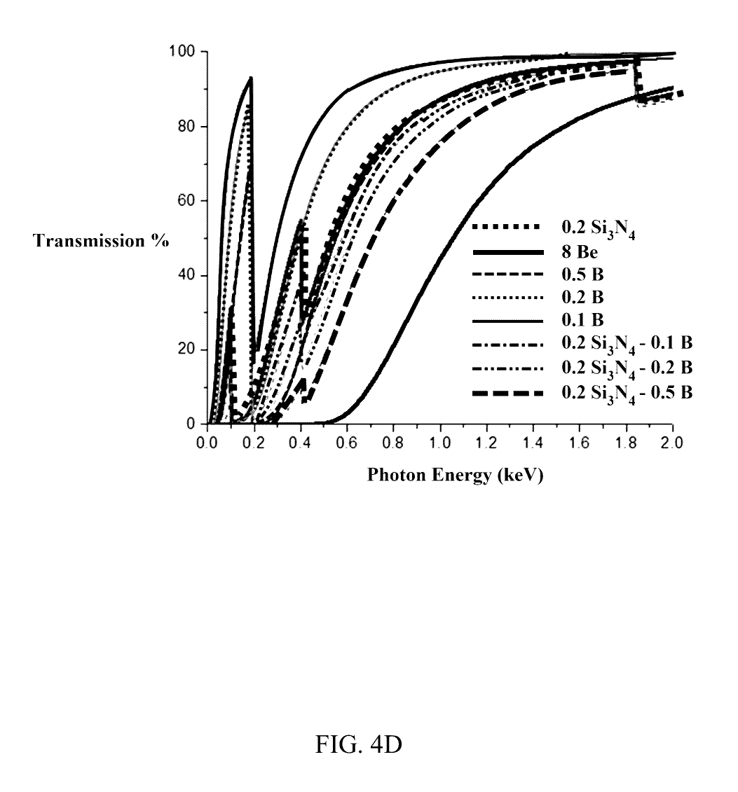

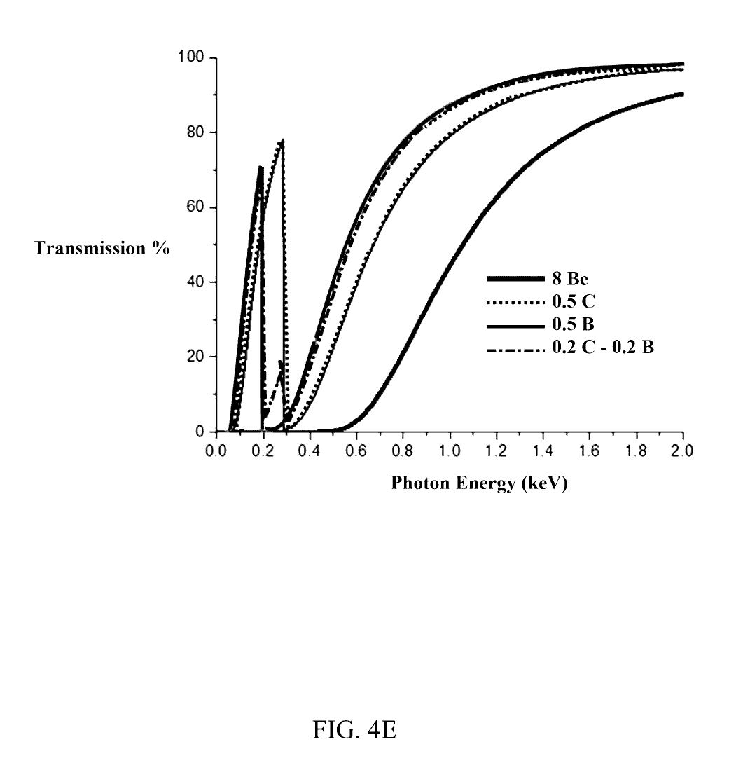

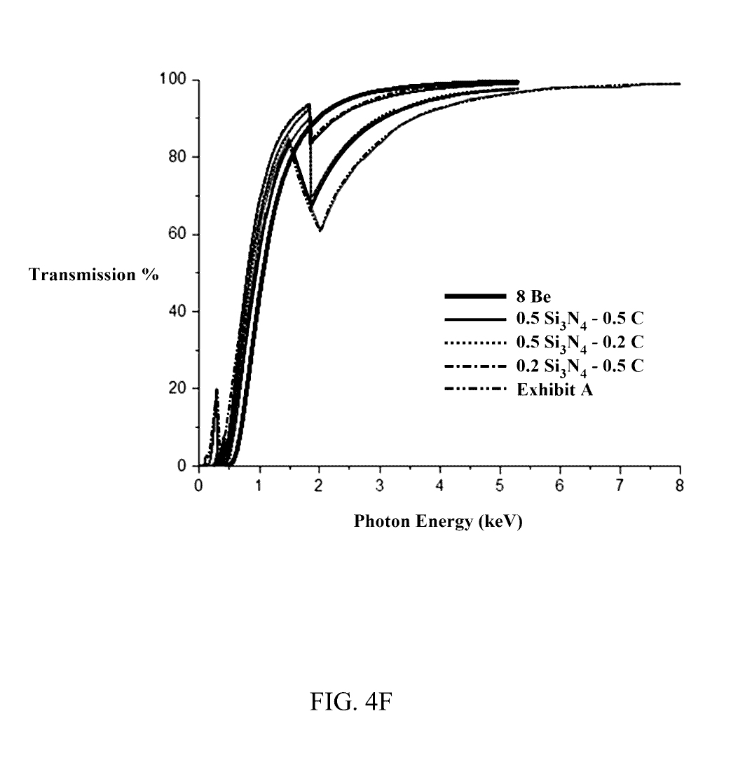

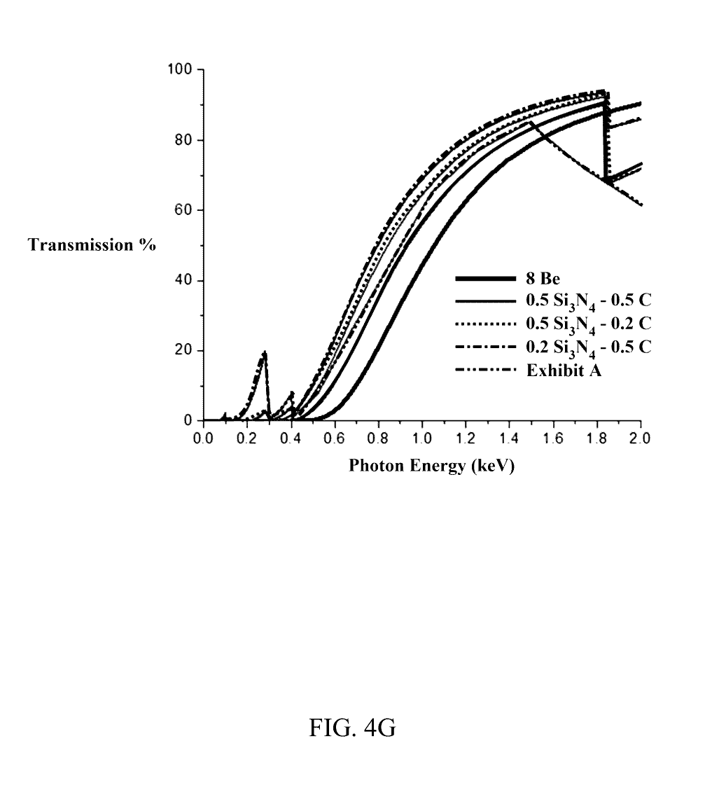

Note however, that any combination of window materials disclosed herein may be deposited onto a silicon wafer 201 and achieve the desired results. For example, any of the combinations of window materials noted by FIGS. 4A-4G may be utilized within embodiments of the present invention.

FIG. 2B illustrates a deposition of a hard mask for use in patterning the materials 201-202 for making the x-ray window 210. A SiO₂ layer 203 may be deposited by PECVD on a back side of a Si wafer 201 as a hard mask (e.g., with a thickness of about 2 μm). A photoresist layer may then be deposited for producing the x-ray window pattern with a bore therethrough (forming an aperture 205). The photoresist is exposed to UV light (e.g., with an exposition dose of about 350 mJ/cm² for about 40 seconds) to define the patterns 204 to be dry and wet etched to produce the windows. The UV light exposure parameters depend on the intensity's tamp. The developer used may be a commercially available MF-26A.

As can be seen in FIG. 2C, by dry etching, the photoresist and SiO₂ 203 are removed only in the patterning area, leaving the Si wafer exposed ready for the deep etching processes.

FIG. 2D illustrates deep etching of the silicon 201 by dry and wet etching processes in order to create the final window configuration 205. Dry etching may be performed with a BOSCH process utilizing an Oerlikon PLASMA-THERM system (e.g., deep silicon etching using a Plasma-based BOSCH process-Thermal plasma ICP etcher). Wet etching may be performed by a KOH 45% etchant at about 85° C. for about 2 hours, depending on the wafer's doping concentration, with the purpose of removing the silicon 201 remaining over the window material(s) 202.

As can be seen, these deep etching processes remove the silicon 201 to produce the x-ray window aperture 205 so that only the window materials 202 remain across (spanning) the aperture formed by the silicon ring structure 204 (which may take the structure of a cylinder). Within embodiments of the present invention, the x-ray window is configured so that it does not include any supporting structures (e.g., frames, screens, meshes, ribs, or grids) spanning the aperture for supporting the window materials 202.

FIG. 2E illustrates a finally formed x-ray window 210 after it has been released from the surrounding silicon wafer 201. Many release agents can be used, including salt, sugar, soap, and a mixture of Betaine monohydrate and sucrose.

With the foregoing manufacturing process, a plurality of such x-ray windows 210 can be easily manufactured.

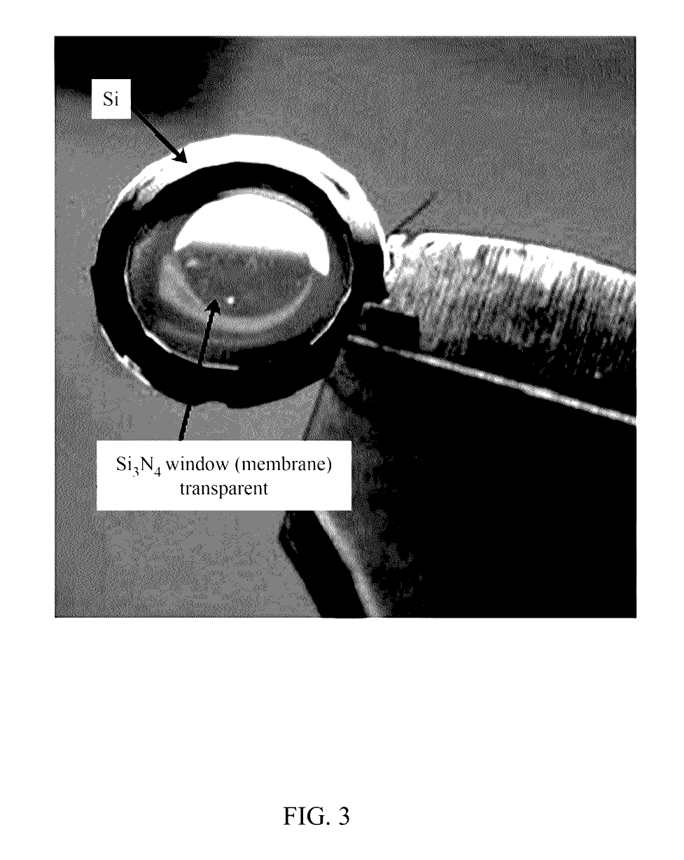

FIG. 3 shows a digital image of a sample of a ring-type x-ray window fabricated by this process, where the diameter of the window 205 through which x-rays can pass can be about 5 mm-9 mm. However, x-ray windows produced by the processes disclosed herein may be manufactured with other diameter dimensions. Moreover, a thickness of the silicon ring 204 supporting the window materials 202 may be manufactured with varying thicknesses (e.g., 200-500 microns).

FIGS. 4A-4G show graphs of x-ray transmission (%) versus photon energy (keV) for various combinations of window materials manufactured in accordance with embodiments of the present invention, which were compared to an 8 μm beryllium (Be) x-ray window (the thickness of Be was fixed as an 8 μm standard).

Window materials utilized for these comparisons were carbon, boron, aluminum, Be, Si₃N₄ and their various combinations with thickness variations. The graphs show that all of the combinations of window materials show as good as or better transmission properties than an 8 μm thick Be window.

FIG. 4A compares the percentage of photon energy transmitted for a 0.5 micron silicon nitride Si₃N₄ window, a 0.2 micron silicon nitride window, a 0.1 micron aluminum (Al) window, a 0.5 micron diamond (C) window, and a 0.5 micron boron (B) window, as compared to an 8 micron beryllium (Be) window. As can be seen, each of these windows manufactured in accordance with embodiments of the present invention performed better than the beryllium window, including being able to allow transmission of greater than 50% of the photon energy for photon energies greater than 0.8 keV.

FIG. 4B shows a graph of photon energy transmission for the following x-ray windows manufactured in accordance with embodiments of the present invention: a 0.2 micron silicon nitride window, a 0.5 micron diamond (C) window, a 0.2 micron diamond (C) window, a 0.1 micron diamond (C) window, a window that includes a 0.2 micron silicon nitride layer in combination with a 0.1 micron diamond (C) layer, an x-ray window having a 0.2 micron silicon nitride layer in combination with a 0.2 micron diamond (C) layer, and a window having a combination of layers of a 0.2 micron silicon nitride layer paired with a 0.5 micron diamond (C) layer. All of these window materials were also compared to an 8 micron beryllium window. As shown in FIG. 4B, all of the foregoing window materials performed better than the beryllium window, including having an x-ray transmission of greater than 50% for photon energies of 0.8 keV and greater.

FIG. 4C compares the x-ray transmission capabilities of an 8 micron beryllium window to the following x-ray windows configured in accordance with embodiments of the present invention: a 0.2 micron silicon nitride window, a 0.1 micron aluminum window, and a window having a combination of layers of a 0.2 micron silicon nitride layer and a 0.1 micron aluminum layer. FIG. 4C shows that all of these combinations of x-ray windows performed better than the beryllium window, including having a greater than 50% transmission for photon energies of 0.6 keV and greater.

FIG. 4D shows a graph of photon energy transmission for the following x-ray windows manufactured in accordance with embodiments of the present invention: a 0.2. micron silicon nitride window, a 0.5 boron (B) window, a 0.2 micron boron (B) window, a 0.1 micron boron (B) window, a window that includes a 0.2 micron silicon nitride layer in combination with a 0.1 micron boron (B) layer, an x-ray window having a 0.2 silicon nitride layer in combination with a 0.2 micron boron (B) layer, and a window having a combination of layers of a 0.2 micron silicon nitride layer paired with a 0.5 micron boron (B) layer. All of these window materials were also compared to an 8 micron beryllium window. As shown in FIG. 4D, all of the foregoing window materials performed better than the beryllium window, including having an x-ray transmission of greater than 50% for photon energies of 0.8 keV and greater.

FIG. 4E shows a comparison of an 8 micron beryllium window to the following x-ray windows configured in accordance with embodiments of the present invention: a 0.5 micron diamond (C) window, a 0.5 micron boron window, and a window having a 0.2 micron diamond (C) layer in combination with a 0.2 micron boron layer. FIG. 4F shows that the x-ray windows configured in accordance with embodiments of the present invention performed better than the beryllium window, including having a greater than 50% transmission of photon energy for photon energies of about 0.7 keV and greater.

FIGS. 4F-4G show plots of photon energy transmission percentages comparing an 8 micron beryllium window to the following x-ray windows configured in accordance with embodiments of the present invention: an x-ray window having a 0.5 micron silicon nitride layer in combination with a 0.5 micron diamond (C) layer, an x-ray window having a 0.5 micron silicon nitride layer in combination with a 0.2 micron diamond (C) layer, and an x-ray window with a 0.2 micron silicon nitride layer in combination with a 0.5 micron diamond (C) layer. Furthermore, the plot lines labeled as Exhibit A represent a satisfactory photon energy transmission behavior of a minimum x-ray window requirement suggested by Moxtek.

The x-ray windows made from a combination of Si₃N₄ and diamond layers with ≦1 μm (in this example, 0.7 μm) in thickness show satisfactory behavior to the x-ray window requirement labeled as Exhibit A.

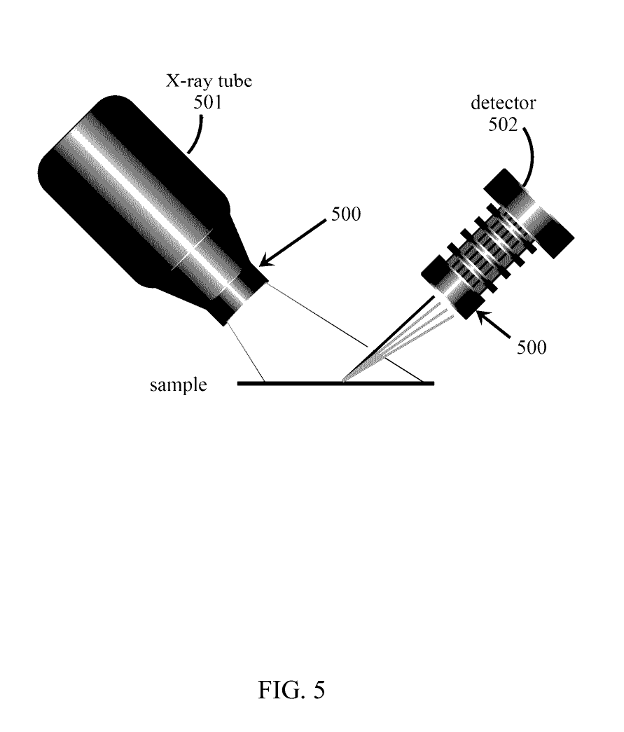

Referring to FIG. 5, x-ray windows 500 configured in accordance with embodiments of the present invention can be used for enclosing an x-ray source 501 or x-ray detection device 502. The window 500 can be used to separate ambient air from a vacuum within the enclosure while allowing passage of x-rays through the window 500. Embodiments of the present invention allow for a pressure difference of one atmosphere or greater in between the interior parts of an x-ray source 501 or detector 502 and the surrounding environment (e.g., ambient air). Thus, an x-ray window 500 configured in accordance with embodiments of the present invention can be used for example when the pressure inside the x-ray source 501 or detector 502 essentially corresponds to that of a vacuum, and the pressure in the exterior environment (e.g., ambient air) is one atmosphere, or even in an opposite case, when a gas pressure is formed inside the x-ray source 501 or detector 502, and the x-ray source 501 or detector 502 itself is located within a vacuum. X-ray windows configured in accordance with embodiments of the present invention may be used in circumstances where the pressure difference is below one atmosphere, or even when the pressure is equal on both sides of the x-ray window.

For example, the x-ray window 210 of FIG. 2E may be utilized with an x-ray source 501 or x-ray detection device 502. The silicon ring 204 may be brazed or fit sealed to a cap (e.g., a nickel-plated Kovar cap) for use in such devices.

As used herein, the term “about” is used to provide flexibility to a numerical range endpoint by providing that a given value may be “a little above” or “a little below” the endpoint.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking, the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

The singular forms “a,” “an,” and “the” include plural referents unless the context clearly⁻ dictates otherwise.

As used herein, “adjacent” refers to the proximity of two structures or elements. Particularly, elements that are identified as being “adjacent” may be either abutting or connected. Such elements may also be near or close to each other without necessarily contacting each other. The exact degree of proximity may in some cases depend on the specific context.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a defacto equivalent of any other member of the same list solely based on their presentation in a common group without indications to the contrary.

Concentrations, amounts, and other numerical data may be presented herein in a range format. It is to be understood that such range format is used merely for convenience and brevity and should be interpreted flexibly to include not only the numerical values explicitly recited as the limits of the range, hut also to include all the individual numerical values or sub-ranges encompassed within that range as if each numerical value and sub-range is explicitly recited. For example, a numerical range of approximately 1 to approximately 4.5 should be interpreted to include not only the explicitly recited limits of 1 to approximately 4.5, but also to include individual numerals such as 2, 3, 4, and sub-ranges such as 1 to 3, 2 to 4, etc. The same principle applies to ranges reciting only one numerical value, such as “less than approximately 4.5,” which should be interpreted to include all of the above-recited values and ranges. Further, such an interpretation should apply regardless of the breadth of the range or the characteristic being described.

Any steps recited in any method or process claims may be executed in any order and are not limited to the order presented in the claims. Means-plus-function or step-plus function limitations will only be employed where for a specific claim limitation all of the following conditions are present in that limitation: a) “means for” or “step for” is expressly recited; and b) a corresponding function is expressly recited. The structure, material, or acts that support the means-plus function are expressly recited in the description herein. Accordingly, the scope of the invention should be determined solely by the appended claims and their legal equivalents, rather than by the descriptions and examples given herein.

Unless defined otherwise, all technical and scientific terms used herein have the same meaning as commonly understood to one of ordinary skill in the art to which the presently disclosed subject matter belongs. Although any methods, devices, and materials similar or equivalent to those described herein can be used in the practice or testing of the presently disclosed subject matter, representative methods, devices, and materials are now described.

Following long-standing patent law convention, the terms “a” and “an” mean “one or more” when used in this application, including the claims.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in this specification and attached claims are approximations that can vary depending upon the desired properties sought to be obtained by the presently disclosed subject matter.

As used herein, “significance” or “significant” relates to a statistical analysis of the probability that there is a non-random association between two or more entities. To determine whether or not a relationship is “significant” or has “significance,” statistical manipulations of the data can be performed to calculate a probability, expressed as a “p value.” Those p values that fall below a user-defined cutoff point are regarded as significant. In some embodiments, a p value less than or equal to 0.05, in some embodiments less than 0.01, in some embodiments less than 0.005, and in some embodiments less than 0.001, are regarded as significant. Accordingly, a p value greater than or equal to 0.05 is considered not significant.

As used herein, the term “and/or” when used in the context of a listing of entities, refers to the entities being present singly or in combination. Thus, for example, the phrase “A, B, C, and/or D” includes A, B, C, and I) individually, but also includes any and all combinations and subcombinations of A, B, C, and D. The term “comprising,” which is synonymous with “including,” “containing,” or “characterized by,” is inclusive or open-ended and does not exclude additional, unrecited elements or method steps. “Comprising” is a term of art used in claim language which means that the named elements are present, but other elements can be added and still form a construct or method within the scope of the claim.

What is claimed is:

1. A method for making an x-ray window comprising:
depositing one or more layers of x-ray transmissive materials onto a silicon substrate; and
patterning and etching the silicon substrate to form a ring structure having an aperture formed therethrough so that only the one or more layers of x-ray transmissive materials cover the aperture.

2. The method as recited in claim 1, wherein the silicon ring structure has a thickness of about 200 microns-500 microns.

3. The method as recited in claim 1, wherein the one or more layers of x-ray transmissive layers have a total thickness of ≦1 micron.

4. The method as recited in claim 1, wherein the one or more layers of x-ray transmissive layers have a total thickness of ≦0.5 microns.

5. The method as recited in claim 1, wherein the one or more layers of x-ray transmissive materials comprise a base layer and a visible light blocking layer.

6. The method as recited in claim 1, wherein the aperture has a diameter of about ≧5 mm.

7. The method as recited in claim 1, wherein the one or more layers include a silicon nitride layer.

8. The method as recited in claim 7, wherein the one or more layers include a diamond thin film.

9. The method as recited in claim 8, wherein the one or more layers of x-ray transmissive layers have a total thickness of ≦1 micron.

10. An x-ray window comprising:
a silicon ring; and
one or more layers of x-ray transmissive materials completely covering an aperture formed in the silicon ring, wherein the one or more layers have a total thickness for passage of x-rays of ≦1 micron.

11. The x-ray window as recited in claim 10, wherein the one or more layers have a total thickness tor passage of x-rays of ≦0.5 microns.

12. The x-ray window as recited in claim 11, wherein the one or more layers have a total thickness for passage of x-rays of ≦0.5 microns.

13. The x-ray window as recited in claim 10, wherein a thickness of the silicon ring is about 200 mm-500 mm.

14. The x-ray window as recited in claim 10, wherein the aperture has a diameter of ≧5 mm.

15. The x-ray window as recited in claim 10, wherein the one or more layers comprise a silicon nitride layer and a diamond thin film.

16. The x-ray window as recited in claim 10, wherein the materials are selected from the group consisting of Si₃N₄, C, B, BN, CN, CNO, BNO, BO₂, LiH, LiF, Al, UNCD, and any combination thereof.

17. The x-ray window as recited in claim 1, wherein the one or more layers of materials are configured to have a photon energy transmission of >50% for photon energies of 0.8 keV.

18. The x-ray window as recited in claim 1, wherein the one or more layers of materials do not include any supporting structures spanning the aperture.

19. The x-ray window as recited in claim 10, wherein the one or more layers consist of a silicon nitride layer and a diamond thin film, wherein a total thickness of the one or more layers is less than or equal to 7 microns.

20. An x-ray window consisting of:
a silicon ring; and
one or more layers of x-ray transmissive materials completely covering an aperture formed in the silicon ring, wherein the one or more layers have a total thickness for passage of x-rays of ≦1 micron.
